(19) United States
(12) Patent Application Publication
(10) Pub. No.: US 2026/0313900 A1
(43) Pub. Date: Oct. 8, 2026

(54) Method for Forming a Memory Structure for a 3D NAND Flash Memory

(71) Applicant: IMEC VZW, Leuven (BE)

(72) Inventors: Sana Rachidi, Leuven (BE); Maarten Rosmeulen, De Pinte (BE); Silvia Armini, Heverlee (BE); Geert Van den Bosch, Kessel-Lo (BE)

(21) Appl. No.: 19/639,838

(22) Filed: Apr. 6, 2026

(30) Foreign Application Priority Data
Apr. 7, 2025 (EP) 25168751.3

(51) Int. Cl. H10B 43/35; H10B 43/27

(52) U.S. Cl. CPC H10B 43/35; H10B 43/27

(57) ABSTRACT

Example embodiments relate to a method for forming a memory structure for a three-dimensional NOT-AND. The method includes forming a layer stack over a substrate. Further, the method includes forming recessed areas in a sidewall surrounding a memory hole in the layer stack. Moreover, the method includes forming a blocking oxide layer in each recessed area. Also, the method includes conformally depositing a liner layer on exposed surfaces in the memory hole. Additionally, the method includes depositing a sacrificial layer on the liner layer. Still further, the method includes etching back the sacrificial layer and removing exposed portions of the liner layer. Moreover, the method includes removing portions of the sacrificial layer in the recessed areas. Also, the method includes forming a discrete charge trap layer in each recessed area, depositing a tunneling oxide layer in the memory hole, and depositing a channel layer on the tunneling oxide layer.

### CROSS-REFERENCE TO RELATED APPLICATIONS

The present application is a non-provisional patent application claiming priority to European patent EP 25168751.3, filed Apr. 07, 2025, the contents of which are hereby incorporated by reference.

### FIELD OF THE DISCLOSURE

The present disclosure relates to forming a memory structure for a 3D NAND flash memory.

### BACKGROUND

The bit density in the 3D NAND flash memory road map may increase every year. Thus far, the increase has been facilitated by increasing the number of stacked memory cells along the vertical dimension. However, this route may become increasingly difficult and costly. Hence, there may be increasing interest in techniques for scaling the cells along the vertical dimension. Vertical scaling (“z-pitch scaling”) may be facilitated by reducing the thickness of the layers in the layer stack, e.g. the word line (gate) layers and oxide inter-gate spacer layers.

Current 3D NAND technology may be based on the so-called charge trap cell utilizing a charge trap layer (e.g., of silicon nitride (SiN)) as a storage layer. The charge trap layer may be deposited as a continuous layer along the sidewall of the memory hole in the layer stack. Z-scaling may result in a reduced inter-cell separation, which in turn may reduce the retention performance of the continuous charge trap layer. There may be a desire for scalable techniques that facilitate forming of an interrupted charge trap layer such that each memory cell may be provided with a separate charge trap layer.

### SUMMARY

The present disclosure relates to forming a memory structure suitable for a three-dimensional (3D) NOT-AND (NAND) flash memory, which may facilitate reliable forming of an interrupted/cut charge trap layer also at aggressive z-pitch scaling.

Hence, according to an aspect of the present disclosure, there is provided a method for forming a memory structure for a 3D NAND flash memory. The method includes forming a layer stack over a substrate, the layer stack including an alternating sequence of gate layers and inter-gate spacer layers. The method also includes forming recessed areas in a sidewall surrounding a memory hole in the layer stack by laterally etching back the gate layers relative to the inter-gate spacer layers from the memory hole. Further, the method includes forming a discrete blocking oxide layer in each recessed area. A thickness of each blocking oxide layer in a lateral direction is less than a depth of each recessed area in the lateral direction. Moreover, the method includes conformally depositing a continuous liner layer on exposed surfaces in the memory hole. The liner layer covers the blocking oxide layer in each recessed area. In addition, the method includes depositing a continuous sacrificial layer on the liner layer. Yet further, the method includes etching back the sacrificial layer such that the liner layer is exposed outside the recessed areas and discrete portions of the sacrificial layer remain in the recessed areas. Still further, the method includes removing exposed portions of the liner layer while using the discrete sacrificial layer portions as an etch mask such that discrete portions of the liner layer covered by the discrete sacrificial layer portions remain in the recessed areas. Moreover, the method includes removing the discrete portions of the sacrificial layer in the recessed areas. Also, the method includes forming a discrete charge trap layer in each recessed area. Each charge trap layer is deposited on the discrete liner layer portion remaining in each recessed area by a (first) area-selective deposition process while using the discrete liner layer portion as a seeding layer. Further, the method includes subsequent to forming the charge trap layers, depositing a tunneling oxide layer in the memory hole. Additionally, the method includes depositing a channel layer on the tunneling oxide layer.

Thus, the method according to the present aspect may facilitate forming of a memory structure that includes vertically separated lateral memory stacks, each including a respective discrete blocking oxide layer and a respective discrete charge trap layer for each gate layer or, equivalently, for each memory cell.

Rather than depositing a continuous charge trap layer and subsequently “cutting” the charge trap layer into a number of discrete portions by etching, the method may “directly” deposit the discrete charge trap layers using an area selective deposition process (ASD). The (discrete) liner layer portions in the recessed areas may be used to define seeding (deposition-promoting) areas (“growth areas”) for the charge trap material of the charge trap layers. Deposition of the charge trap material in areas vertically between the gate layers may hence be avoided (i.e., on end surfaces of the inter-gate spacer layers facing the memory hole), which may thus obviate the need for cutting a continuous layer of charge trap material by etching. When obviating the need for cutting the charge trap material by etching, the lateral thickness of the charge trap layers (i.e., the thickness dimension as seen along the lateral direction) may be precisely controlled by maintaining the growth conditions of the selective deposition until a target thickness has been achieved.

A material choice for the inter-gate spacer layers may be an oxide (e.g. silicon oxide). Therefore, ASD of charge trap material on the blocking oxide layers in the recessed areas without any appreciable concurrent deposition on the inter-gate spacer layers may be challenging. However, by the conformal deposition of a continuous liner layer, followed by deposition and etch back of a sacrificial layer, discrete liner layer portions configured as seeding layers for the ASD of charge trap material may be formed in a reliable manner within the recessed areas. Thereby, charge trap material may be deposited with improved area selectivity. That is, the discrete liner layer portions may be localized to the recessed areas and may be formed of a material selected to facilitate the ASD of the charge trap material.

In some embodiments, the discrete blocking oxide layer may be deposited on the etched-back gate layer in each recessed area by a (second) area-selective deposition process.

Hence, the blocking oxide material of the blocking oxide layers may be deposited by ASD. During the ASD of the blocking oxide material, the gate layers may define deposition-promoting (seeding) areas contributing to a preferential deposition of the blocking oxide material in the recessed areas.

In some embodiments, the discrete blocking oxide layer may be formed by oxidizing a portion of the etched-back gate layer in each recessed area, such that the oxidized portion may form the discrete blocking oxide layer on a non-oxidized portion of the etched-back gate layer.

This may facilitate forming of the discrete blocking oxide layers in an area-selective manner, within the recessed areas. In particular, discrete blocking oxide layers may be formed also in cases where the materials of the gate layers and the inter-gate spacer layers provide limited contrast for ASD. This approach may be used where the gate layers are formed of a material that may be oxidized into a species of oxide suitable as a blocking oxide, such as silicon oxide. The gate layers may be formed of a silicon-comprising material, for instance silicon nitride, amorphous silicon (a-Si) or polysilicon.

In some embodiments, the portions of the etched-back gate layer may be oxidized by a thermal oxidation process.

The blocking oxide layers may thus be formed using a simple, reliable, and cost-effective process which further may be relatively benign to non-targeted layers, such as the inter-gate spacer layers. A thermal oxidation process may also facilitate a reliable oxidation in high-aspect ratio structures.

In some embodiments, the portions of the etched-back gate layer may be oxidized by a plasma oxidation process.

In some embodiments, the liner layer may include a metal oxide or a metal nitride. Such liner/seeding layer materials (e.g., aluminum oxide, hafnium oxide, titanium oxide, or titanium nitride) may facilitate process control as they may define efficient deposition-promoting surfaces with respect to ASD of the charge trap material, for example relative to non-metal oxide or non-metal nitride (typically silicon oxide) inter-gate spacer layers. Further metal oxides or metal nitrides may be reliably deposited as continuous and conformal layers, e.g., using atomic layer deposition (ALD).

In some embodiments, the sacrificial layer may be deposited to completely fill a remaining space in each recessed area. This may improve process control by providing an additional margin against over-etching during etching back the sacrificial layer. Thus, this may make it easier to facilitate discrete portions of the sacrificial layer remaining to cover the liner layer in the recessed areas after completing the etch back.

In some embodiments, the charge trap layers may be a silicon-comprising layer, such as silicon nitride layers. Silicon-comprising layers may be suitable for charge trap layers. Silicon nitride may represent an efficient and rational realization of charge trap-based memory cells. Further, silicon nitride may be suitable for ASD onto conformal metal oxides or metal nitrides, without causing any appreciable co-deposition onto silicon oxide.

In some embodiments, the gate layers may be silicon-comprising layers, such as silicon nitride layers, a-Si layers, or polysilicon layers. Such layers may facilitate final functional gates to be formed in a replacement metal gate (RMG) process. Polysilicon gate layers (e.g., when highly doped) may be used as functional gates in the final devices.

In some embodiments, the gate layers may be sacrificial gate layers and the method may further include subsequent to forming the charge trap layers, replacing the sacrificial gate layers by a replacement metal gate layer. The sacrificial gate layers may thus be replaced with functional metal gate layers by an RMG process. The sacrificial gate layers may be removed by etching back the sacrificial gate layers from a second hole (e.g., an “access trench”) in the layer stack, different from the memory hole, and subsequently forming RMG layers replacing the sacrificial gate layers. The RMG layers may be formed subsequent to depositing the tunneling oxide layer and the channel layer.

### BRIEF DESCRIPTION OF THE FIGURES

The above, as well as additional, features will be better understood through the following illustrative and non-limiting detailed description of example embodiments, with reference to the appended drawings.

FIG. 1a shows a cross-sectional view of a structure for forming a memory structure, according to example embodiments.

FIG. 1b shows a top-down view of a structure for forming a memory structure, according to example embodiments.

FIG. 2 shows the structure after forming recessed areas, according to example embodiments.

FIG. 3 shows the structure after forming blocking oxide layers in the recessed areas, according to example embodiments.

FIG. 4 shows the structure after depositing a continuous conformal liner layer, according to example embodiments.

FIG. 5 shows the structure after depositing sacrificial layer on the liner layer, according to example embodiments.

FIG. 6 shows the structure after etching back the sacrificial layer, according to example embodiments.

FIG. 7 shows the structure after etching back the liner layer, according to example embodiments.

FIG. 8 shows the structure after removing sacrificial layer portions from the recessed areas, according to example embodiments.

FIG. 9 shows the structure after growing charge trap layers in the recessed areas, according to example embodiments.

FIG. 10 shows the structure after forming tunnel barrier and channel layers, according to example embodiments.

FIG. 11 shows the structure after a replacement metal gate process, according to example embodiments.

FIG. 12 shows an alternative approach for forming blocking oxide layers in the recessed areas, according to example embodiments.

FIG. 13 shows an alternative approach for forming blocking oxide layers in the recessed areas, according to example embodiments.

All the figures are schematic, not necessarily to scale, and generally only show parts which are necessary to elucidate example embodiments, wherein other parts may be omitted or merely suggested.

### DETAILED DESCRIPTION

Example embodiments will now be described more fully hereinafter with reference to the accompanying drawings. That which is encompassed by the claims may, however, be embodied in many different forms and should not be construed as limited to the embodiments set forth herein; rather, these embodiments are provided by way of example. Furthermore, like numbers refer to the same or similar elements or components throughout.

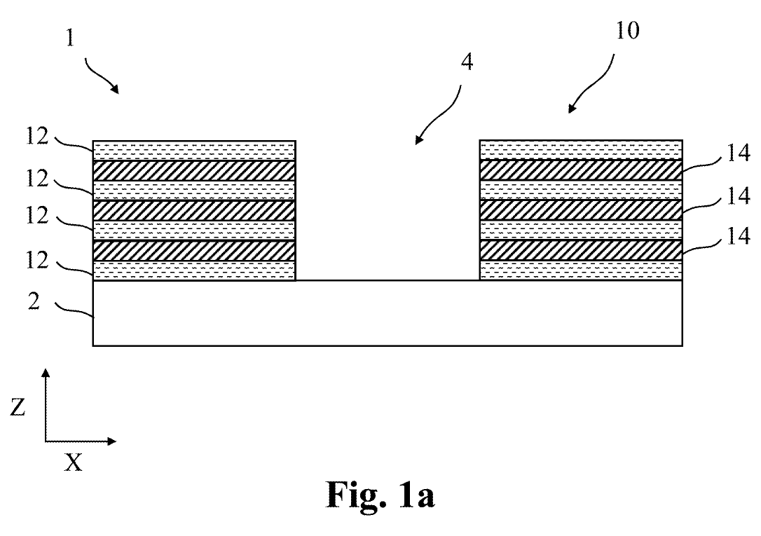

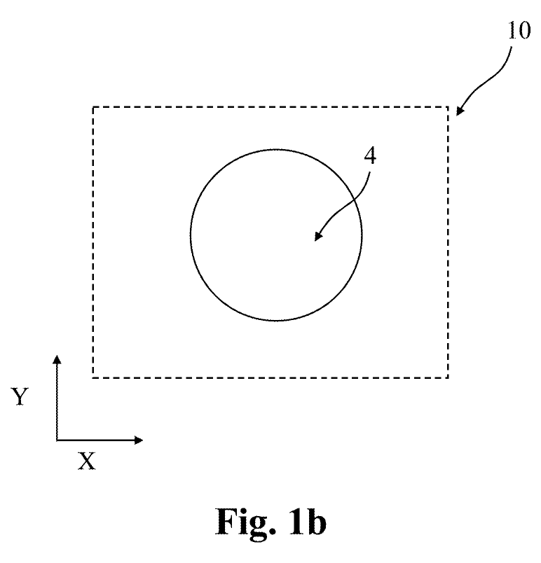

Embodiments of a method for forming a memory structure for a 3D NAND flash memory, such as a 3D-Gate-All-Around-NAND (3D GAA NAND), may be described with reference to the drawings. The drawings are only schematic and the relative dimensions of some structures and layers may be exaggerated and not drawn to scale. Rather the dimensions may be adapted for illustrational clarity and to facilitate understanding. When present in the figures, the indicated axes X, Y and Z consistently refer to a first horizontal or lateral direction, a second horizontal or lateral direction, and a vertical direction, respectively. As used herein, the terms “horizontal” and “lateral” refer to directions parallel to (a main surface of) a supporting substrate of the memory structure. A lateral/horizontal direction may also be understood as a direction parallel to an in-plane direction of the gate and inter-gate spacer layers. The term “vertical” refers to a direction parallel to a normal direction to (the main surface of) the substrate, i.e. transverse to the substrate. Reference is herein also made to a “radial” direction. This term is to be understood as a radial direction with respect to a given memory hole (e.g., memory hole 4 in FIG. 1a), parallel to the horizontal XY-plane. The terms “radially inward” and “radially outward” accordingly refers to radially inward and outward directions, respectively, with respect to a given memory hole. Related terms, such as “radially inner”, “radially and “radially outer” may correspondingly be used to indicate a relative radial location or distance of a feature or element, relative to the given memory hole.

FIG. 1a shows a cross-sectional view of a structure 1 for forming a memory structure, according to example embodiments.

FIG. 1b shows a top-down view of a structure 1 for forming a memory structure, according to example embodiments.

Structure 1 may include layer stack 10 that may include a precursor or starting structure for the memory structure, to be subjected to the processing steps of the method disclosed in the following.

Layer stack 10 may be formed over substrate 2 and may include an alternating sequence of gate layers 14 and inter-gate spacer layers 12. Inter-gate spacer layers 12 and gate layers 14 may be stacked on top of each other along the vertical direction Z.

Substrate 2 may be a substrate suitable for semiconductor processing and for supporting a memory structure for a 3D NAND flash memory. Substrate 2 may be a Si substrate, a Ge substrate or a SiGe substrate. Other examples may include a silicon-on-insulator (SOI) substrate, a GeOI substrate or a SiGeOI substrate.

Gate layers 14 may be silicon-comprising layers, such as SiN layers, a-Si layers or polysilicon layers, that may form sacrificial gate layers 14 that may be intended to be replaced by an RMG stack in subsequent process steps. Gate layers 14 may also be functional gate layers, e.g. highly doped polysilicon-comprising layers.

Inter-gate spacer layers 12 may be oxide-comprising layers, such as silicon oxide (e.g., SiO₂) layers or another suitable inter-layer dielectric (e.g., of low-k). Inter-gate spacer layers 12 may be arranged in layer stack 10 to provide vertical separation between the memory cells / word lines of the memory device that may be formed.

Layer stack 10 may be formed by interchangeably depositing layers of gate material (e.g. nitride) and inter-gate spacer material (e.g. oxide) using deposition processes, such as chemical vapor deposition (CVD), physical vapor deposition (PVD), or atomic layer deposition (ALD).

Inter-gate spacer layer 12 and gate layers 14 may be formed in numbers in accordance with the number of stacked memory cells of the memory device. It is to be noted that the number of inter-gate spacer layer 12 and gate layers 14 of the illustrated layer stack 10 is a non-limiting example and that the method disclosed herein may be compatible with stacks of memory cells of any number, such as 64, 128, 256, or greater.

Inter-gate spacer layers 12 and gate layers 14 may each be formed with a respective layer thickness in a range of 5-25 nm, as an example. A z-pitch of layer stack 10 (i.e., the combined thickness of one of inter-gate spacer layers 12 and one of gate layers 14) may be in a range from about 45 nm to 15 nm or less.

While omitted for ease of illustration, layer stack 10 may be capped by a capping layer, for instance a semiconductor layer (e.g., silicon), deposited on top of the top-most of inter-gate spacer layers 12. A capping layer may serve to protect the top-most of inter-gate spacer layers 12 during the following processing.

After depositing the inter-gate spacer layer 12 and gate layers 14 (and optionally a capping layer) of layer stack 10, memory hole 4 may be patterned in layer stack 10, e.g. by a lithography and etching process. While FIGS. 1a and 1b shows a portion of layer stack 10 surrounding single memory hole 4, it is noted that a corresponding memory hole 4 may be patterned at each location where a respective vertical string of memory cells is desired. Memory hole 4 may as shown be formed to extend through each one of inter-gate spacer layers 12 and gate layers 14 of layer stack 10. Memory hole 4 may, as further shown in the top-down view of FIG. 1b, be formed with a circular cross-sectional shape, such that memory hole 4 may be formed with a substantially circular cylindrical shape (footprint). However, memory hole 4 may also be formed with other cross-sectional shapes, such as an oval or polygonal shape.

While not shown in FIG. 1a, layer stack 10 may include underneath inter-gate spacer layer 12 and gate layers 14 , a sub-stack of a select layer and a source layer for forming a select plate and a source plate, respectively, of the memory device. The select and source layers may hence form a bottom sub-stack of layer stack 10. The select and source layers may be formed by doped semiconductor layers (e.g. polysilicon), and be separated by layers of interlayer dielectric.

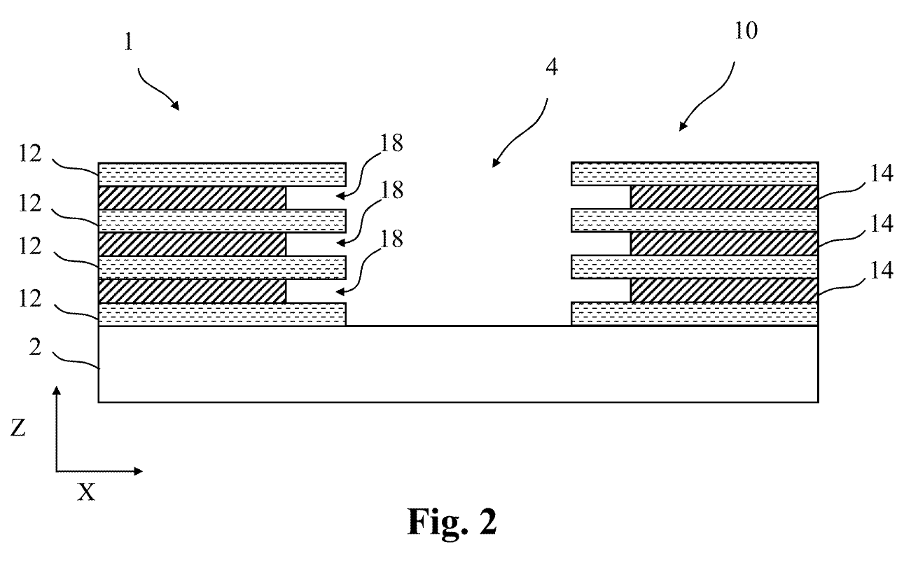

FIG. 2 shows the structure 1 after forming recessed areas, according to example embodiments. As shown in FIG. 2, recessed areas 18 may be formed in a sidewall of layer stack 10 surrounding memory hole 4 by laterally etching back (i.e., in a radially outward direction, along the X-axis) gate layers 14 relative to inter-gate spacer layers 12 from memory hole 4. Thereby, each of recessed areas 18 may be formed between a pair of inter-gate spacer layers 12. Due to the circumferential extension of the sidewall about memory hole 4, recessed areas 18 may extend circumferentially about memory hole 4. In the example of a circular memory hole 4, recessed areas 18 may be annular.

Gate layers 14 may be etched back using an etching process adapted to etch gate layers 14 selectively to inter-gate spacer layers 12. That is, the etching process may be adapted to etch (i.e. remove) the material (e.g. the silicon nitride, a-Si or polysilicon) of gate layers 14 selectively to the material (e.g. the oxide material) of gate layers 14, such that gate layers 14 may be laterally etched back without causing any substantial etch-back of inter-gate spacer layers 12. The etching process may be applied to the sidewall of layer stack 10 via memory hole 4. The etching process may be an isotropic etching process. However, any suitably selective etching process, wet or dry, providing a sufficient lateral etching component for gate layers 14 may be used.

Recessed areas 18 may be formed with a lateral/radial depth (along the X-axis) meeting or exceeding an intended lateral thickness of the lateral memory stacks, e.g., a combined lateral thickness of the blocking oxide and charge trap layers at each gate-level. As may be appreciated, the lateral depth of recessed areas 18 may be determined by the lateral depth (radial extent) of the lateral etch back. The lateral depth of recessed areas 18 may be in a range of 6-20 nm. The depth of recessed areas 18 may be controlled by timing the lateral etch back.

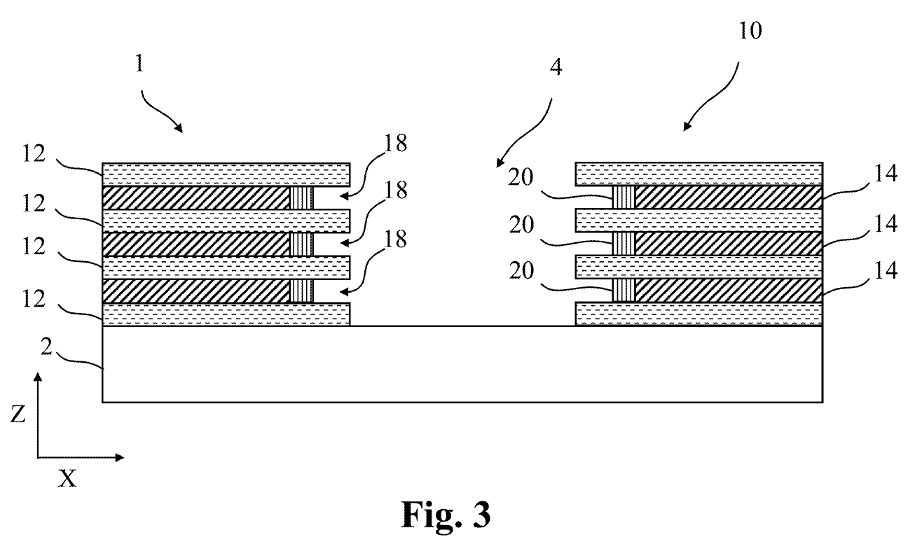

FIG. 3 shows the structure 1 after forming blocking oxide layers in the recessed areas, according to example embodiments. As shown in FIG. 3, a discrete blocking oxide layer 20 may be formed in each recessed area 18. Blocking oxide layers 20 may be formed with a thickness in the X direction being less than the lateral depth of recessed areas 18. Thus, each (discrete) blocking oxide layer 20 may only partially fill a lateral depth of a respective recessed area 18. Hence, also subsequent to forming blocking oxide layers 20, the sidewall of memory hole 4 may define a recessed / profiled sidewall. Discrete blocking oxide layer 20 in each of recessed areas 18 may be formed with a lateral thickness in a range of 4-15 nm. Blocking oxide layers 20 may include silicon oxide (SiO₂), or some other oxide material suitable to be used as a blocking oxide.

Discrete blocking oxide layers 20 may be formed by various approaches. In some embodiments, discrete blocking oxide layers 20 may be deposited on etched-back gate layer 14 in each of recessed areas 18 by an ASD process. Thus, a blocking oxide material for forming the blocking oxide layers 20 may be deposited selectively in the recessed areas 18. The deposition may be continued until discrete portions of blocking oxide material of a target thickness have been deposited in each of recessed areas 18, each portion may define a respective discrete blocking oxide layer 20. During the ASD, the etched-back end surfaces of gate layers 14 facing memory hole 4 may define deposition-promoting (seeding) areas for the blocking oxide material while the inter-gate spacer layers 12 may define deposition-inhibiting (non-growth) areas.

The blocking oxide material may be deposited using any suitable deposition process (e.g. an ALD or CVD process) and may facilitate ASD of the blocking oxide material (e.g. SiO₂) in recessed areas 18.

To facilitate ASD of blocking oxide layers 20, layer stack 10 may be subjected to a treatment process prior to depositing the blocking oxide material, to define growth areas in recessed areas 18 (e.g., on the end surfaces of etched-back gate layers 14) and non-growth areas outside recessed areas 18. The treatment process may be adapted to functionalize the surface portions / end surfaces of etched-back gate layers 14 in recessed areas 18 with respect to the ASD of the blocking oxide material. The treatment process may additionally or alternatively be adapted to passivate exposed surface portions of inter-gate spacer layers 12 with respect to the ASD of the blocking oxide material. Thereafter the blocking oxide material may be deposited selectively in the growth areas in recessed areas 18. For instance, the functionalization may include depositing a deposition-promoting layer on the end surfaces of etched-back gate layers 14 in recessed areas 18. Additionally or alternatively, layer stack 10 may be subjected to a treatment process adapted to passivate exposed surface portions of inter-gate spacer layers 12 with respect to the ASD of blocking oxide material 20. For instance, some deposition processes may favor deposition on hydrogen terminated surfaces (e.g. the deposition process deposits material preferentially on hydrogen terminated surfaces). A treatment process may hence be adapted to increase the occurrence of hydrogen terminated bonds on gate layers 14 (which may thus promote deposition thereon) and/or reduce the occurrence of hydrogen terminated bonds on inter-gate spacer layers 12 (which may thus inhibit deposition thereon). As a further example, silicon oxide (SiO₂) inter-gate spacer layers 12 may be passivated selectively to silicon nitride/a-Si/polysilicon gate layers 14 using siloxanes, aminosilanes, trichlorosilanes, small molecule inhibitors (SMIs, such as dimethylamino-trimethylsilane (DMA-TMS), trimethyltrimethoxysilane, trimethoxytrichlorosilane, etc.) or self-assembled monolayers (SAMs, such as alkylsilanes), which may facilitate ASD of the blocking oxide material on the end surfaces of the gate layers 14.

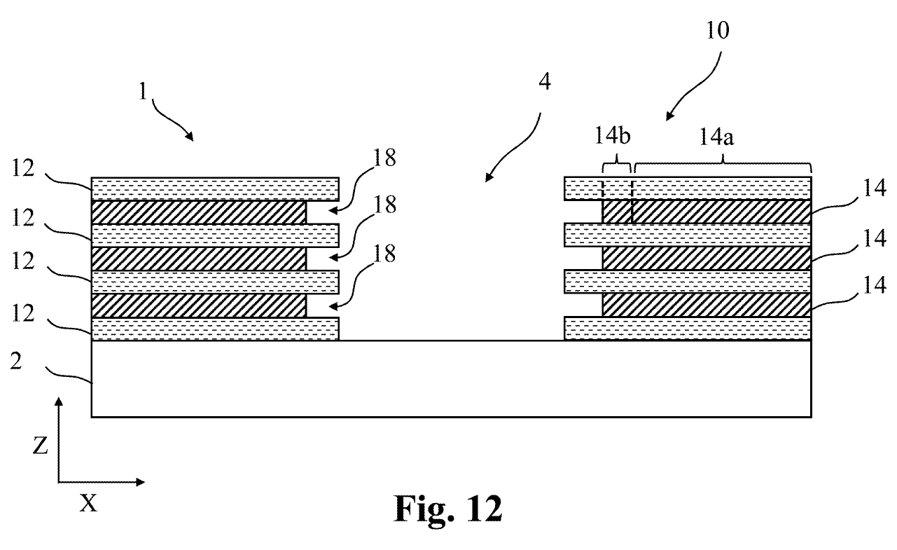

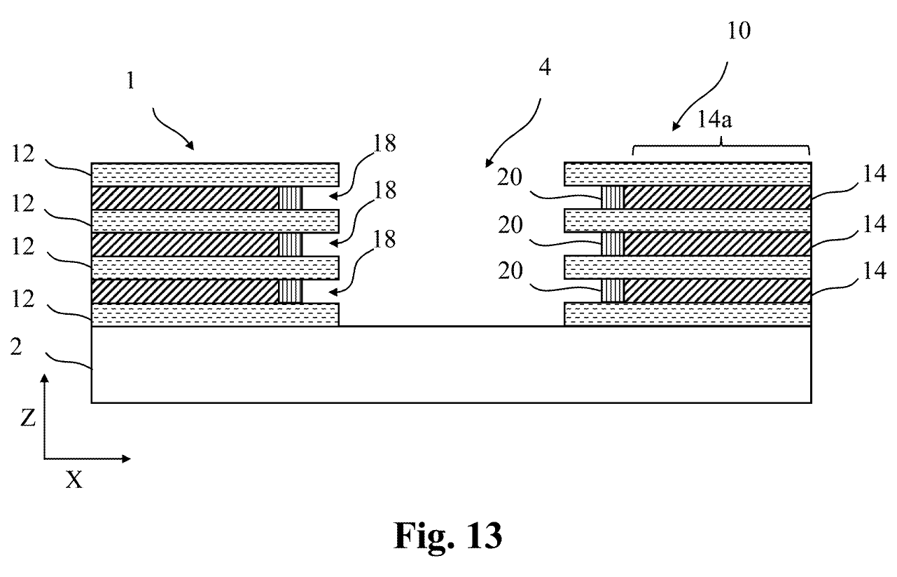

According to another approach, discrete blocking oxide layers 20 may be formed by oxidizing portions of etched-back gate layers 14 in recessed areas 18. This is described in greater detail in reference to FIGS. 12 and 13, which may indicate each blocking oxide layer 20 may be formed by oxidizing portion 14b of etched-back gate layer 14 in a respective of recessed areas 18, wherein portion 14b forms discrete blocking oxide layer 20 on a remaining non-oxidized portion 14a of the gate layer 14. Etched-back gate layers 14 may be exposed to the oxidizing ambient / agent via memory hole 4. Where gate layers 14 are silicon-comprising layers, such as silicon nitride layers, a-Si layers, or polysilicon layers, blocking oxide layers 20 may be formed as silicon oxide (SiO₂) layers. The oxidation process may be a thermal oxidation process. The oxide may be a low-temperature oxide (LTO) or a high-temperature oxide (HTO). The oxidation process may also be a plasma oxidation process. An oxidation-based approach discussed above, may be useful to apply to material combinations when may be challenging to achieve a sufficiently selective deposition of blocking oxide material on gate layers 14, such as when the inter-gate spacer layers 12 include SiO₂.

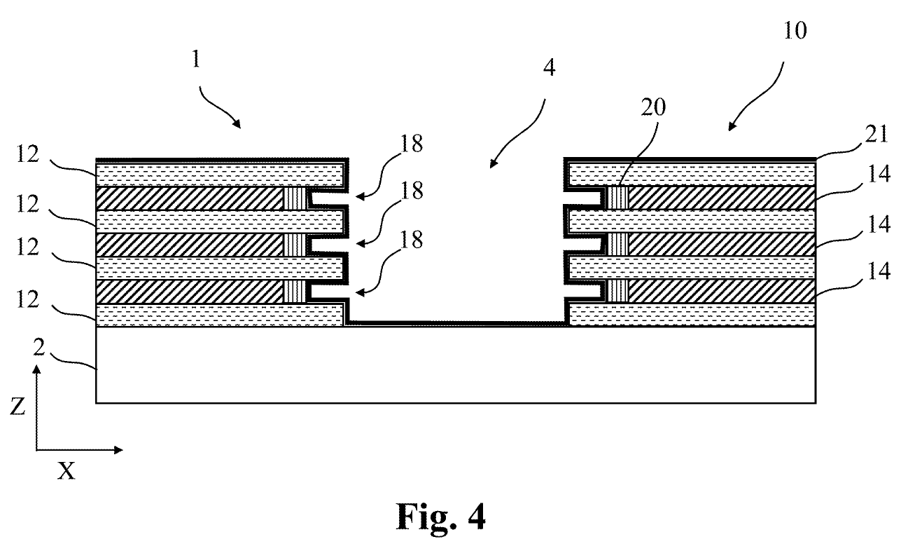

FIG. 4 shows the structure 1 after depositing a continuous conformal liner layer, according to example embodiments. Specifically, FIG. 4 depicts structure 1 at a stage after forming blocking oxide layers 20 (e.g., in accordance with either of the above-discussed approaches) and subsequent to further conformally depositing continuous liner layer 21 on exposed surfaces in memory hole 4. Liner layer 21 may thus cover (e.g., coat or line) exposed surface portions of layer stack 10 facing memory hole 4. Due to the conformal nature of the deposition, liner layer 21 may cover interior surfaces of recessed areas 18, including blocking oxide layer 20 in each of recessed areas 18. As shown in FIG. 4, the interior surfaces of recessed areas 18 may further include surface portions of inter-gate spacer layers 12 above and below each of recessed areas 18. Liner layer 21 may be deposited by ALD, or some other suitable conformal deposition process.

Liner layer 21 may function as a seeding layer during a subsequent ASD step of charge trap material for forming charge trap layers 24 in recessed areas 18. Hence, liner layer 21 may be formed of any material that may be conformally deposited and act as a seeding layer for the ASD of the charge trap material. Liner layer 21 may include a metal oxide or a metal nitride, such as AlOₓ, HfOₓ, TiN, TiO₂, or some other high-k oxide or nitride.

Since recessed areas 18 may further accommodate charge trap layers 24 of some minimum target thickness, liner layer 21 may be as shown deposited to partially fill recessed areas 18. Thus, liner layer 21 may be formed with a thickness that is smaller than a remaining lateral depth (along the X axis) of recessed areas 18 being partially filled with blocking oxide layers 10. Further, the thickness of liner layer 21 may be such that pinch-off of recessed areas 18 may be avoided. The thickness here refers to a local thickness of liner layer 21, i.e., a thickness of liner layer 21 measured in a direction normal to its underlying/supporting surface at the location where the local thickness is measured. To avoid pinch-off, a thickness of liner layer 21 may be less than half a thickness (along the Z-axis) of each of gate layers 14, such as at most a third or a quarter of the thickness of each of gate layers 14, or less. For instance, liner layer 21 may be formed with a thickness of about 2 nm or less, such as about 1 nm. A thickness in this range may be compatible with the above-mentioned thickness ranges of gate layers 14 and blocking oxide layers 20, and the depth range of recessed areas 18.

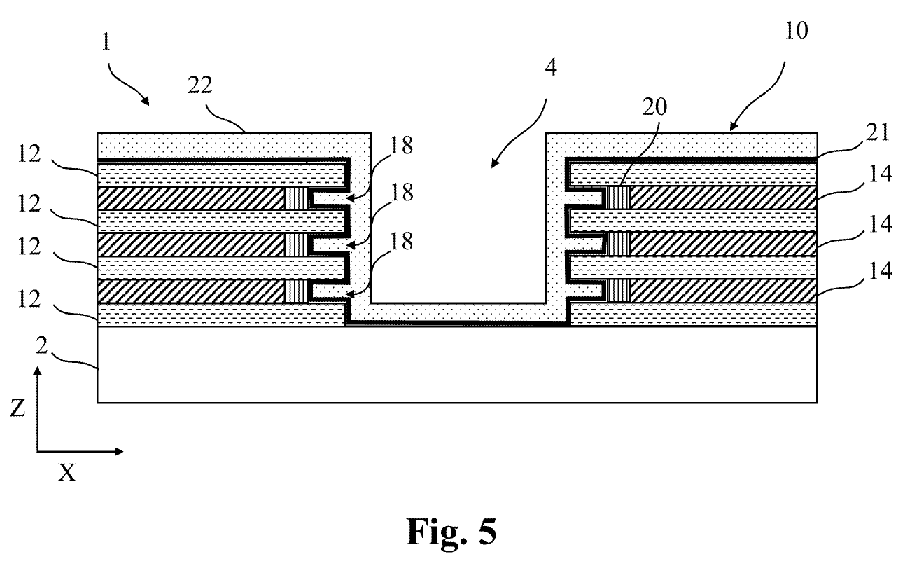

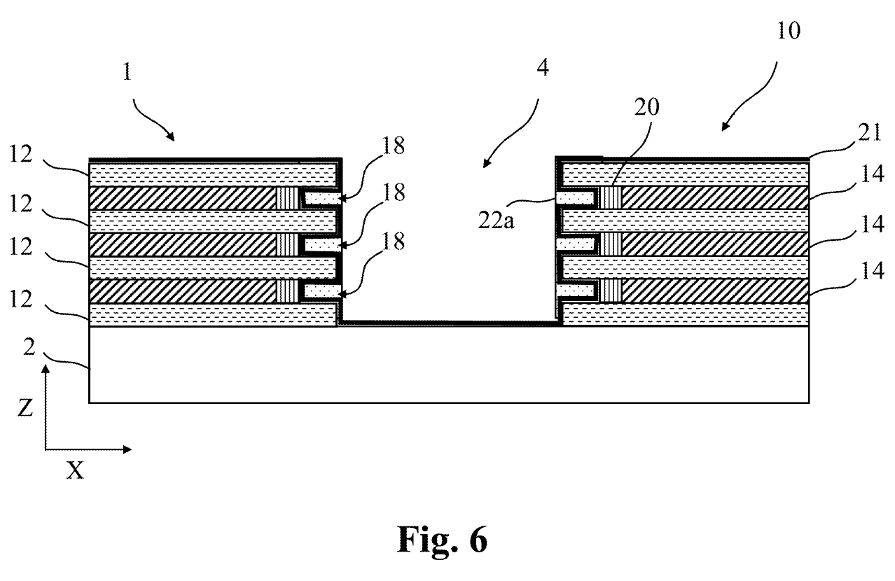

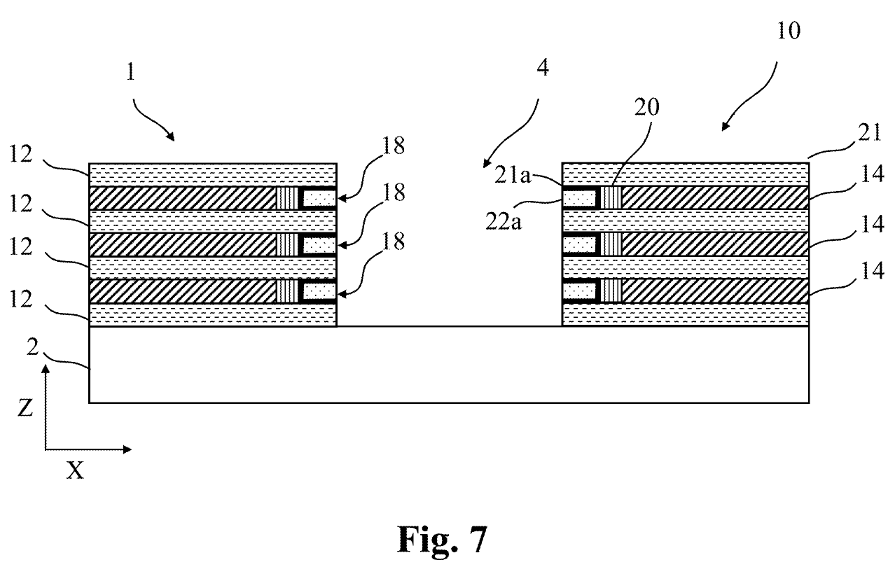

FIG. 5 shows the structure 1 after depositing sacrificial layer on the liner layer, according to example embodiments. As shown in FIG. 5, a continuous sacrificial layer 22 may be deposited on liner layer 21, including on portions of liner layer 21 in the remaining interior spaces of recessed areas 18. Notably, sacrificial layer 22 may be deposited to completely fill a remaining interior space of (within) each of recessed areas 18. The benefit of this may be appreciated from by considering FIGS. 6 and 7.

FIG. 6 shows the structure 1 after etching back the sacrificial layer, according to example embodiments. As shown in FIG. 6, the sacrificial layer 22 may be etched back such that the liner layer 21 may be exposed outside recessed areas 18 and discrete portions 22a of sacrificial layer 22 may remain in recessed areas 18.

FIG. 7 shows the structure 1 after etching back the liner layer, according to example embodiments. As shown in FIG. 7, exposed portions of liner layer 21 (i.e., the portions of liner layer 21 not covered by discrete sacrificial layer portions 22a) may be removed while using discrete sacrificial layer portions 22a (i.e., the remaining discrete portions of etched-back sacrificial layer 22) as an etch mask such that discrete portions 21a of liner layer 21 covered by discrete sacrificial layer portions 22a remain in recessed areas 18. Thus, by having the sacrificial layer 22 completely filling the remaining interior spaces of the recessed areas 18, it discrete sacrificial layer portion 22a may remain to cover liner layer 21 in each of recessed areas 18, upon exposing portions of liner layer 21 outside of recessed areas 18.

While a complete filling of the remaining interior spaces of recessed areas 18 by sacrificial layer 22 may contribute to process reliability, it is contemplated that a sufficient criterion may be that sacrificial layer 22 fills the remaining interior spaces of recessed areas 18 to such an extent that, after the etching back of sacrificial layer 22, discrete sacrificial layer portions 22a are preserved in the recessed areas 18 to such an extent that they may act as an etch mask for liner layer 21. Thus, in any case, by forming the discrete sacrificial layer portions 21a in the recessed areas 18, discrete liner layer portions 21a may be preserved after the subsequent etch back of liner layer 21.

As shown in FIG. 7, the etch back of sacrificial layer 22 may be schematically depicted to restore a sidewall of memory hole 4 to a substantially straight profile. However, this is not a requirement for the functioning of the process. Rather, it may be sufficient that a portion of liner layer 21 in each of recessed areas 18, in particular the portion extending along the end surface of gate layer 14 associated with the particular recessed area of recessed areas 18, is covered by a discrete sacrificial layer portion 22a, such that it may be masked and preserved during the subsequent etch back of liner layer 21. Thus, a slight lateral over etching of sacrificial layer portions 22a into recessed areas 18 may not reduce process yield.

As sacrificial layer 22 may serve as an etch mask during etch back of liner layer 21, sacrificial layer 22 may be formed of any sacrificial material that may be deposited to fill the remaining interior spaces of recessed areas 18, and that may provide a sufficient etch contrast with respect to liner layer 21 such that it may be used as an etch mask for liner layer 21, and that eventually may be removed from inter-gate spacer layers 12 without causing collateral damage to structure 1. Examples of sacrificial materials may include semiconductors, metals, polymers or insulators. For example, the sacrificial material may be Si, SiN, SiCN, TiN, W (e.g., if the liner is TiN) or Mo, to name a few non-limiting examples.

Sacrificial layer 22 may be deposited by conformal, as well as non-conformal deposition processes, as long as the deposition process allows sacrificial material to be deposited to fill recessed areas 18. Non-limiting examples may include CVD, ALD as well as spin-on deposition.

The etch back of sacrificial layer 22 may be facilitated by any suitable isotropic etching process, wet or dry. Liner layer 21 may be used for etch-stop detection, however a timed etch back is also possible.

The etch back of liner layer 21 may be realized by any suitable isotropic etching process, wet or dry. Inter-gate spacer layers 12 may be used for etch-stop detection. A timed etch back is also possible. As liner layer 21 may be deposited to define a relatively thin layer (e.g., 2 nm or less), a relatively brief etch step may suffice to remove the exposed portions of liner layer 21.

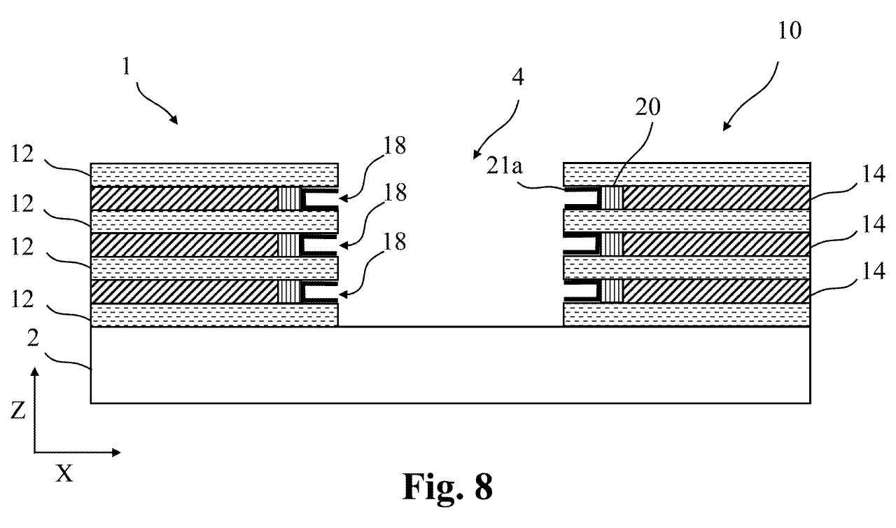

FIG. 8 shows the structure 1 after removing sacrificial layer portions from the recessed areas, according to example embodiments. As shown in FIG. 8, the discrete sacrificial layer portions 22a may be removed from recessed areas 18, thus exposing discrete liner layer portions 21a in recessed areas 18. Sacrificial layer portions 22a may be removed using any suitable isotropic etching process, wet or dry, such as an etching processed used during the etch back of sacrificial layer 22 discussed with reference to FIG. 6.

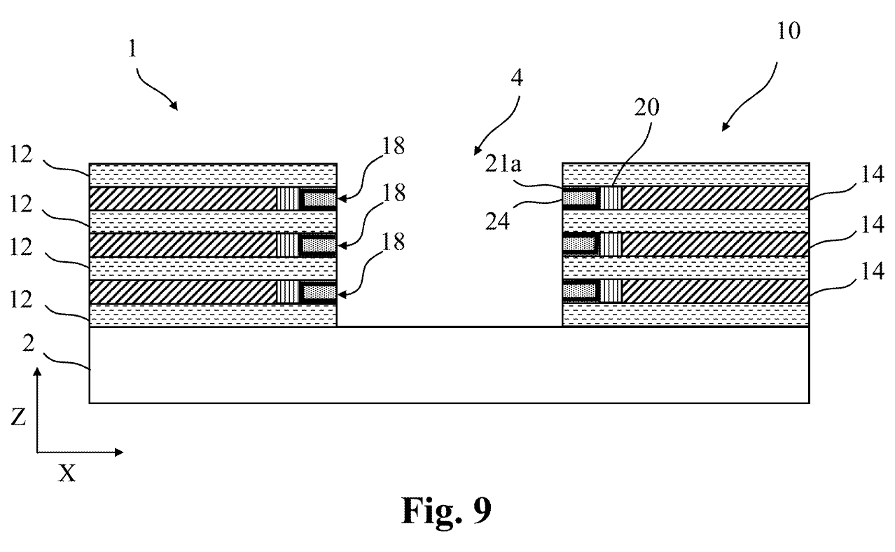

FIG. 9 shows the structure 1 after growing charge trap layers in the recessed areas, according to example embodiments. As shown in FIG. 9, a discrete charge trap layer 24 may be formed in each of recessed areas 18. Each of charge trap layers 24 may be deposited on a respective discrete liner layer portion 21a. Charge trap layers 24 may be formed by an ASD process using discrete liner layer portions 21a as a seeding layer. Thus, charge trap material may be deposited selectively in recessed areas 18, seeding from (nucleating on) discrete liner layer portions 21a therein.

The deposition of the charge trap material may be continued until discrete portions of charge trap material of a target thickness have been deposited in recessed areas 18, each portion defining a respective discrete charge trap layer of charge trap layers 24. During the ASD, inter-gate spacer layers 12 may define deposition-inhibiting (non-growth) areas while liner layer portions 21a define deposition-promoting (seeding) areas for the charge trap material.

The charge trap material may include silicon nitride (SiN, i.e. Si₃N₄). Silicon nitride may represent an efficient and rational realization of charge trap memory cells. Silicon nitride may for instance be deposited by ASD onto any of the above-mentioned examples of liner materials (metal oxides or metal nitrides such as AlOₓ, HfOₓ, TiN, TiO₂). More generally, the charge trap material may include silicon, meaning that charge trap layers 24 may be silicon-comprising layers. Composite layer structures of charge trap layers 24 may also be possible. For example, charge trap layers 24 may include first and second sequentially deposited layers (sub-layers), wherein the first sub-layer may be a silicon or silicon-comprising layer, and the second sub-layer may be a metal layer such as TiN or Ru. The present method may be compatible with other choices of charge trap material, such as those that may be deposited in an area-selective fashion on liner layer portions 21a in recessed areas 18. The charge trap material may be deposited using any suitable deposition process, conformal or non-conformal, such as an ALD or CVD process.

To facilitate the ASD of the charge trap material, layer stack 10 may be subjected to a treatment process prior to depositing the charge trap material, to define growth areas in recessed areas 18 (e.g., on liner layer portions 21a) and non-growth areas outside recessed areas 18. The treatment process may be adapted to (further) functionalize liner layer portions 21a with respect to the ASD of the charge trap material. The treatment process may additionally or alternatively be adapted to passivate exposed surface portions of inter-gate spacer layers 12 with respect to the ASD of the charge trap material. Thereafter the charge trap material may be deposited selectively on the growth areas in recessed areas 18. The examples of functionalization and passivation discussed above with reference to ASD of blocking oxide material apply correspondingly to ASD of charge trap material. As a specific non-limiting example, a SiO₂ surface may be passivated by DMA-TMS inhibition selectively to either TiO₂ or TiN.

Discrete charge trap layers 24 may each be formed with a lateral thickness (along the X axis) in a range of 4-8 nm. More generally, discrete charge trap layers 24 may be formed to completely fill the remaining interior spaces of recessed areas 18. End surfaces of discrete charge trap layers 24 facing memory hole 4 may thus become substantially flush with the end surfaces of inter-gate space layers 12 facing memory hole 4. In other words, a sidewall of memory hole 4 may (e.g., again) be restored to a substantially straight profile, or at least with a reduced topography compared prior to forming charge trap layers 24.

As depicted in FIG. 9, each of recessed areas 18 may be provided with (e.g., “re-filled” and/or “re-grown” with) discrete blocking layer 20, liner layer portion 21a, and charge trap layer 24. These layers may define a lateral memory stack for respective gate layer of gate layers 14.

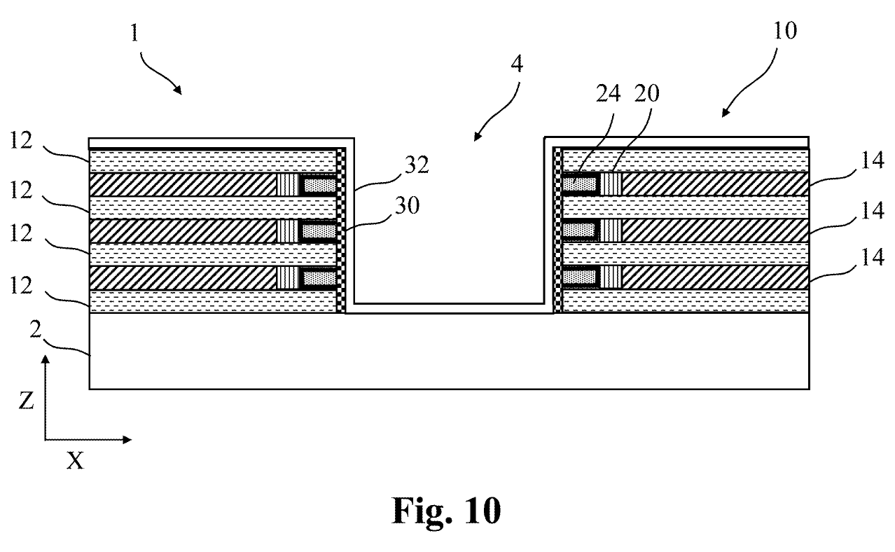

FIG. 10 shows the structure 1 after forming tunnel barrier and channel layers, according to example embodiments. As shown in FIG. 10, tunnelling oxide layer 30, and channel layer 32, may be formed in memory hole 4, along the sidewall thereof. Tunnelling oxide layer 30 may be thus formed along discrete charge trap layers 24 of the lateral memory stacks, more specifically along or in contact with the respective inner end surfaces of charge trap layers 24 facing memory hole 4. Tunnelling oxide layer 30 and channel layer 32 may each be conformally deposited, e.g. using a respective ALD process. After depositing tunnelling oxide layer 30, tunnelling oxide layer 30 may be subjected to an anisotropic etch oriented top-down (opposite the direction of the Z-axis) to remove portions of tunnelling oxide layer 30 deposited on horizontally oriented surfaces of structure 1.

Tunnelling oxide layer 30 may be formed of any material used for tunnelling oxide layers, one non-limiting example being SiON. Channel layer 32 may be formed by any channel material for channel layers, such as a semiconductor material (e.g., Si, SiGe or Ge). While not shown in FIG. 10, channel layer 32 may present an extension outside of the illustrated portion of structure 1, which may facilitate connection to peripheral semiconductor devices and circuitry, such as select transistors.

Subsequently, memory hole 4 may be filled with a plug or filler material 34, such as an inter-layer dielectric (e.g., SiO₂) or other low-k dielectric. If gate layers 14 are sacrificial gate layers, the method may as further shown proceed with replacing sacrificial gate layers 14 by replacement metal gate layers or stacks 36. Sacrificial gate layers 14 may be removed by etching back sacrificial gate layers 14 from a second hole (e.g., an “access trench,” not shown) in layer stack 10 (e.g. denoting memory hole 4 as a front side hole or opening the second hole may be referred to as a backside hole or opening). The formed laterally/radially extending gate cavities formed at the levels of sacrificial gate layers 14 may subsequently be filled with a RMG layer or stack, which may replace sacrificial gate layers 14. The gate cavities may be etched using an isotropic etching process. For example, the gate cavities may be etched using a same type of etching process as used to form recessed areas 18.

The RMG process may comprise depositing one or more conductive layers, e.g. metal such as one or more of TiN and W. The deposition of the conductive layer(s) may be preceded by deposition of a (conformal) high-k gate dielectric.

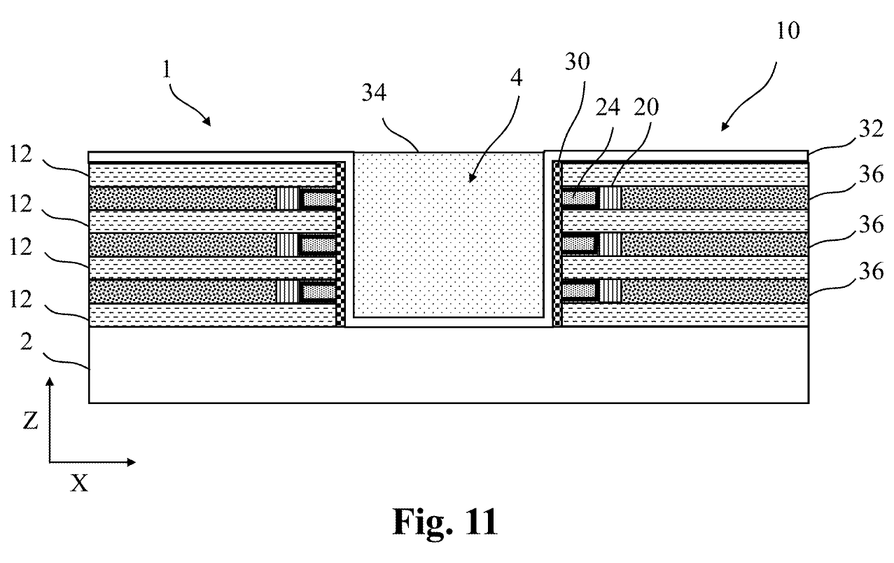

FIG. 11 shows the structure 1 after a replacement metal gate process, according to example embodiments. At the stage of the process illustrated in FIG. 11, memory structure 1 may include, for each gate level, a discrete blocking layer 20 and a discrete charge trap layer 24. These layers may define a lateral memory stack between a respective gate layer/stack 36 and the (shared) tunnel barrier and channel layers 30, 32.

The process may further proceed with process steps of 3D NAND fabrication. For example, structure 1 may be further processed to contact each gate layer 14/36 to peripheral semiconductor devices and circuitry, such as select transistors and wordline drivers. Contact formation may for example be preceded with patterning the gate layers 14/36 into a staircase structure.

FIG. 12 shows an alternative approach for forming blocking oxide layers in the recessed areas, according to example embodiments.

FIG. 13 shows an alternative approach for forming blocking oxide layers in the recessed areas, according to example embodiments.

While some embodiments have been illustrated and described in detail in the appended drawings and the foregoing description, such illustration and description are to be considered illustrative and not restrictive. Other variations to the disclosed embodiments can be understood and effected in practicing the claims, from a study of the drawings, the disclosure, and the appended claims. The mere fact that certain measures or features are recited in mutually different dependent claims does not indicate that a combination of these measures or features cannot be used. Any reference signs in the claims should not be construed as limiting the scope.

What is claimed is:

1. A method, comprising:
forming a layer stack over a substrate, wherein the layer stack comprises an alternating sequence of gate layers and inter-gate spacer layers;
forming recessed areas in a sidewall surrounding a memory hole in the layer stack by laterally etching back the gate layers relative to the inter-gate spacer layers from the memory hole to produce a plurality of etched-back gate layers;
for each of the recessed areas, forming a blocking oxide layer, wherein a thickness of each blocking oxide layer in a lateral direction is less than a depth of the recessed area in the lateral direction;
conformally depositing a liner layer on exposed surfaces in the memory hole, wherein the liner layer covers the blocking oxide layer in each of the recessed areas;
depositing a sacrificial layer on the liner layer;
etching back the sacrificial layer such that the liner layer is exposed outside the recessed areas and discrete portions of the sacrificial layer remain in the recessed areas;
removing exposed portions of the liner layer while using the discrete portions of the sacrificial layer as an etch mask such that discrete portions of the liner layer covered by the discrete portions of the sacrificial layer remain in each of the recessed areas;
for each of the recessed areas, removing the discrete portions of the sacrificial layer;
for each of the recessed areas, forming a charge trap layer, wherein the charge trap layer is deposited on the discrete portions of the liner layer remaining in the recessed area by a first area-selective deposition process while using the discrete portions of the liner layer as a seeding layer;
subsequent to forming the charge trap layers, depositing a tunnelling oxide layer in the memory hole; and
depositing a channel layer on the tunnelling oxide layer.

2. The method of claim 1, wherein, for each of the recessed areas, the blocking oxide layer is deposited on each of the plurality of etched-back gate layers by a second area-selective deposition process.

3. The method of claim 1, wherein the blocking oxide layer is formed by oxidizing a portion of each of the plurality of etched-back gate layers in each of the recessed areas thereby forming an oxidized portion such that the oxidized portion forms the blocking oxide layer on a non-oxidized portion of each of the plurality of etched-back gate layers.

4. The method of claim 3, wherein, for each of the plurality of etched-back gate layers, the portion is oxidized by a thermal oxidation process.

5. The method of claim 3, wherein, for each of the plurality of etched-back gate layers, the portion is oxidized by a plasma oxidation process.

6. The method of claim 1, wherein the liner layer comprises a metal oxide.

7. The method of claim 1, wherein the liner layer comprises a metal nitride.

8. The method of claim 1, wherein the sacrificial layer completely fills a remaining space in each of the recessed areas.

9. The method of claim 1, wherein each of the charge trap layers comprises silicon.

10. The method of claim 1, wherein each of the charge trap layers comprises silicon nitride.

11. The method of claim 1, wherein, for each of the recessed areas, the blocking oxide layer has a lateral thickness between 4 nanometers and 12 nanometers.

12. The method of claim 1, wherein each of the charge trap layers has a lateral thickness between 4 nanometers and 8 nanometers.

13. The method of claim 1, wherein the liner layer has a thickness of 2 nanometers or less.

14. The method of claim 1, wherein the inter-gate spacer layers have a thickness between 5 nanometers and 25 nanometers.

15. The method of claim 14, wherein the gate layers have a thickness between 5 nanometers and 25 nanometers.

16. The method of claim 15, an inter-gate spacer layer of the inter-gate spacer layers and a gate layer of the gate layers have a combined thickness of 45 nanometers or less.

17. The method of claim 1, wherein the gate layers are sacrificial gate layers.

18. The method of claim 17, further comprising:
subsequent to forming the charge trap layers, replacing the sacrificial gate layers by a replacement metal gate layer.

19. The method of claim 18, wherein the replacement metal gate layer is formed subsequent to depositing the tunnelling oxide layer.

20. The method of claim 19, wherein the replacement metal gate layer is formed subsequent to depositing the channel layer.
